(19) United States
(12) Patent Application Publication
(10) Pub. No.: US 2020/0102430 A1
(43) Pub. Date: Apr. 2, 2020

(54) ELECTROCHEMICAL MIGRATION-INHIBITING ADDITIVE AND METHOD FOR INHIBITING ELECTROCHEMICAL MIGRATION USING THE SAME

(71) Applicant: Research & Business Foundation Sungkyunkwan University, Suwon-si (KR)

(72) Inventor: Jung Gu KIM, Seongnam-si (KR)

(73) Assignee: Research & Business Foundation Sungkyunkwan University, Suwon-si (KR)

(21) Appl. No.: 16/582,160

(22) Filed: Sep. 25, 2019

(30) Foreign Application Priority Data
Sep. 27, 2018 (KR) 10-2018-0114868

(51) Int. Cl. C08J 5/00; H01L 23/29

(52) U.S. Cl. CPC C08J 5/00; C08K 5/1535; C08J 2363/00; H01L 23/295

(57) ABSTRACT

Disclosed are an additive for suppressing electrochemical migration (ECM) in an electrical wire, and a method of inhibiting the ECM using the additive. A solution containing the ECM-inhibiting additive may inhibit creation of dendrite to prolong an ECM time. The additive as proposed may be mixed with polymer materials such as epoxy molding compound (EMC) or underfill materials used for packaging a semiconductor, or the like. Alternatively, the additive as proposed may be added to metal electrical wires to improve the reliability of semiconductor devices.

### CROSS-REFERENCE TO RELATED APPLICATION

This application claims the benefit under 35 U.S.C. § 119(a) of Korean Patent Application No. 10-2018-0114868 filed on Sep. 27, 2018, in the Korean Intellectual Property Office, the entire disclosure of which is incorporated herein by reference for all purposes.

### BACKGROUND

### 1. Field

The present disclosure relates to an electrochemical migration-inhibiting additive and a method of inhibiting electrochemical migration using the additive.

### 2. Description of Related Art

As market for high-performance and high-reliability electronic components expands, high density and high integration in which a line width of a metal electrical wire or a thickness of a bonding layer between two layers in electronic components is reduced is progressing. This has caused reliability issue of the electronic components. In general, a metal electrical wire of an electronic component is made of a metal such as copper (Cu) or silver (Ag) that has excellent electrical conductivity and excellent thermal conductivity and is inexpensive. However, the electrical wire of the electronic component is exposed to moisture, and electricity flows between two electrical wires, such that electrochemical migration (ECM) occurs in an electrical circuit. This causes an electrical short in the circuit, shortening a lifespan of the electronic component.

A reaction mechanism of the ECM of metal may include following three steps:

First step: anode reaction

M (Metal)→Mⁿ⁺+ne⁻

2H₂O→O₂+4H⁺+4e⁻

M+H₂O→MO+2H⁺+2e⁻

Second step: cathode reaction

Mⁿ⁺+ne⁻→M

O₂+2H₂O+4e⁻→4OH⁻

2H₂O+2e⁻→H₂+2OH⁻

Third step: inter-electrode reaction

2M⁺+2OH⁻→M₂O+H₂O

M²⁺+2OH⁻→M(OH)₂

The ECM allows the anode metal to be electrochemically ionized. Then, the ionized metal ions are reduced and precipitated on the cathode due to a potential difference between the anode and the cathode, thereby creating dendrite to cause an electrical short. As this reaction proceeds, production and decomposition reactions of metal oxide and metal hydroxide occur.

In order to suppress the ECM, there has been proposed a method of applying a polymer-based material to between adjacent metal electrical wire layers. This adds a further process to conventional metal electrical wire fabrication and packaging, resulting in additional time and cost.

In this connection, Korean Patent Application No. 10-2016-0107614 (hereinafter, “prior art”) discloses an additive that inhibits growth of dendrite by increasing triggering points of the ECM to inhibit the ECM.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

The present inventors recognized that the cathode reaction of all metals subjected to the ECM involves the reduction reaction of oxygen (O₂+2H₂O+4e⁻→4OH⁻). Thus, the present inventors discovered from a result of an ECM experiment for Cu and Ag that oxygen removal using an additive (oxygen scavenger) in accordance with the present disclosure inhibits OH⁻ formation and thus the reaction between the electrodes involving OH⁻ may be inhibited to more effectively suppress the ECM of various metals in a semiconductor device.

The additive in accordance with the present disclosure differs from the additive of the above prior art in that the present additive suppresses generation of the ECM by removing oxygen involving the ECM, whereas the prior art additive suppresses the ECM by increasing triggering points of the ECM to inhibit the ECM. That is, the prior art additive is to suppress growth of the dendrite in order to inhibit the ECM, whereas the present additive is to suppress generation of the dendrite using the oxygen scavenging additive.

Therefore, a purpose of the present disclosure is to provide an additive for suppressing ECM generated between metal electrical wires of an electronic component and a method for suppressing the ECM using the additive.

Purposes of the present disclosure are not limited to the above-mentioned purpose. Other purposes and advantages of the present disclosure as not mentioned above may be understood from following descriptions and more clearly understood from embodiments of the present disclosure. Further, it will be readily appreciated that the purposes and advantages of the present disclosure may be realized by features and combinations thereof as disclosed in the claims.

In a first aspect of the present disclosure, there is provided an additive for inhibiting electrochemical migration (ECM) in an electrical wire, the additive including at least one selected from a group consisting of ascorbic acid (C₆H₈O₆), carbohydrazide ((N₂H₃)₂CO), hydroquinone (C₆H₄-1,4(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose:oxygen-1-oxidoreductase), cobalt sulfite (CoSO₃), nitrogen monoxide (NO), and hamamelitannin (2′,5-di-O-galloylhamamelose: C₂₀H₂₀O₁₄).

In one implementation of the first aspect, the additive inhibits creation of dendrite in the electrical wire.

In one implementation of the first aspect, the additive inhibits a cathode reaction involving in the electrochemical migration in the electrical wire, wherein the cathode reaction is represented by a following reaction formula: O₂+2H₂O+4e⁻→4OH⁻.

In a second aspect of the present disclosure, there is provided an epoxy molding compound (EMC) containing the additive for inhibiting the ECM as defined above.

In a third aspect of the present disclosure, there is provided underfill materials containing the additive for inhibiting the ECM as defined above.

In a fourth aspect of the present disclosure, there is provided a metal electrical wire containing the additive for inhibiting the ECM as defined above.

In a fifth aspect of the present disclosure, there is provided a method for inhibiting electrochemical migration (ECM) in an electrical wire, the method comprising: preparing an additive for inhibiting the ECM in an electrical wire; adding the additive into a packaging material or an epoxy molding compound (EMC); and molding the electrical wire using the packaging material or EMC, wherein the additive comprises at least one selected from a group consisting of ascorbic acid (C₆H₈O₆), carbohydrazide ((N₂H₃)₂CO), hydroquinone (C₆H₄-1,4-(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose:oxygen-1-oxidoreductase), cobalt sulfite (CoSO₃), nitrogen monoxide (NO), and hamamelitannin (2′,5-di-O-galloylhamamelose; C₂₀H₂₀O₁₄).

In one implementation of the fifth aspect, the additive inhibits creation of dendrite in the electrical wire.

In one implementation of the fifth aspect, the additive inhibits a cathode reaction involving in the electrochemical migration in the electrical wire, wherein the cathode reaction is represented by a following reaction formula: O₂+2H₂O+4e⁻→4OH⁻.

Effects of the present disclosure are as follows but are not limited thereto.

When comparing a solution containing the ECM-inhibiting additive as proposed in accordance with the present disclosure with the convention solution, it was confirmed that the solution containing the ECM-inhibiting additive may inhibit the creation of dendrite to prolong the ECM time. For this purpose, the present additive was added to a solution for an existing water drop test as a high-acceleration test to measure sensitivity of the ECM. Then, a time for which dendrite grows to extend between two metal electrical wires was measured. The time refers to the electrochemical migration time or ECM time.

The additive proposed in accordance with the present disclosure may be mixed with polymer materials such as epoxy molding compound (EMC) or underfill materials used for packaging a semiconductor, or the like. Alternatively, the additive proposed in accordance with the present disclosure may be added to metal electrical wires to improve the reliability of semiconductor devices.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1A and FIG. 1B are a schematic diagram and an image for illustrating phenomenon of the ECM.

FIG. 2A and FIG. 2B are a schematic diagram and an image for illustrating EM (electro migration).

FIG. 3A to FIG. 3D show an average and a standard deviation of an ECM time based on concentrations of a reference solution and each single-additive containing solution according to the present disclosure for a copper electrical wire.

FIG. 4A and FIG. 4B show an average and a standard deviation of an ECM time based on concentrations of a reference solution and each single-additive containing solution according to the present disclosure for a silver electrical wire.

FIG. 5 shows an average and a standard deviation of an ECM time based on concentrations of each various-additives containing solution according to the present disclosure for a copper electrical wire.

FIG. 6 shows an average and a standard deviation of an ECM time based on concentrations of each various-additives containing solution according to the present disclosure for a silver electrical wire.

FIG. 7 is a schematic showing a mechanism of suppressing cathode reaction using addition of an oxygen scavenger.

### DETAILED DESCRIPTIONS

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure relates to the inhibition of the electrochemical migration (ECM) using an additive. More specifically, the present disclosure relates to the additive for inhibiting the ECM generated in the electrical wire used in an electronic component.

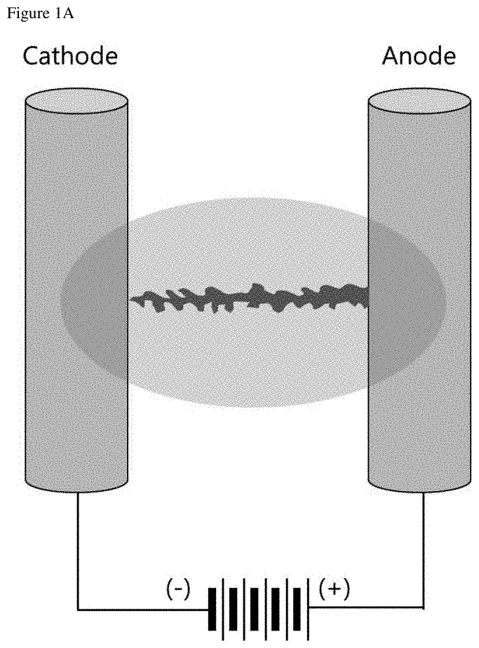

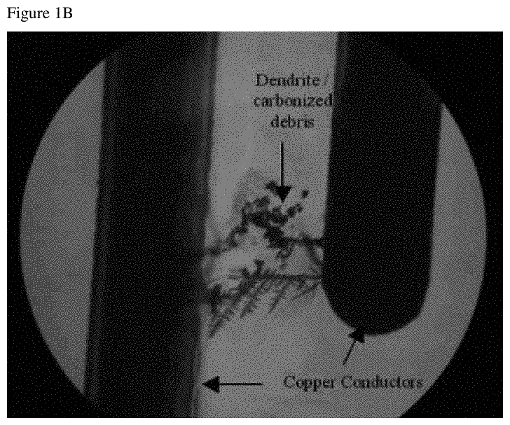

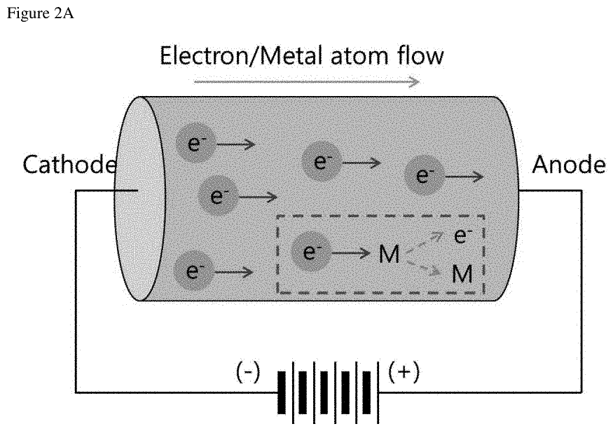

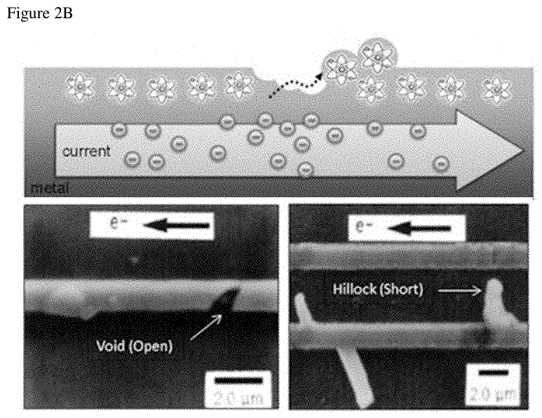

In accordance with the present disclosure, the additive intend to suppress the creation of the ECM itself. The ECM is a phenomenon caused by movement of metal ions between adjacent metal conductors due to formation of dendrite, as shown in FIG. 1A and FIG. 1B. The cause of the ECM may be oxygen due to moisture. Therefore, an additive in accordance with the present disclosure suppresses the creation of the ECM via removal of the oxygen. EM (Electro Migration) is different from the ECM. The EM occurs inside a metal conductor. In the EM, a large number of high-speed electrons collide with the metal atoms, thereby generating simple momentum transfer thereto, and then moving the metal atoms. EM is shown in FIG. 2A and FIG. 2B.

In summary, the ECM refers to a phenomenon occurring between adjacent metal conductors, and typically leads to a short circuit. The EM refers to a phenomenon occurring inside the single conductor, and typically leads to an open circuit.

Korean Patent Application No. 10-2016-0107614 as the prior art discloses an additive that inhibits growth of dendrite by increasing triggering points of the ECM to inhibit the ECM.

The additive in accordance with the present disclosure differs from the additive of the above prior art in that the present additive suppresses generation of the ECM by removing oxygen involving the ECM, whereas the prior art additive suppresses the ECM by increasing triggering points of the ECM to inhibit the ECM. That is, the prior art additive is to suppress growth of the dendrite in order to inhibit the ECM, whereas the present additive is to suppress generation of the dendrite using the oxygen scavenging additive.

In one embodiment of the present disclosure, an additive for inhibiting electrochemical migration (ECM) in an electrical wire may include at least one selected from a group consisting of ascorbic acid (C₆H₈O₆), carbohydrazide ((N₂H₃)₂CO), hydroquinone (C₆H₄-1,4-(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose:oxygen-1-oxidoreductase), cobalt sulfite (CoSO₃), nitrogen monoxide (NO), and hamamelitannin (2′,5-di-O-galloylhamamelose: C₂₀H₂₀O₁₄). The materials listed above may be added alone or in a combination of at least two thereof.

In this connection, the additive inhibits creation of dendrite in the electrical wire. The additive inhibits a cathode reaction involving in the electrochemical migration in the electrical wire, wherein the cathode reaction is represented by a following reaction formula: O₂+2H₂O+4e⁻→4OH⁻.

Therefore, in accordance with the present disclosure, the removal of the oxygen using the additive (oxygen scavenger) inhibits the creation of OH⁻, thereby inhibiting the reaction between the electrodes, that is, the anode and cathode, involving in OH⁻. Thus, the present additive may be considered to be more effective in suppressing the ECM creation in various metals present in a semiconductor device.

In one implementation of the present disclosure, an epoxy molding compound (EMC) may contain the additive for inhibiting the ECM as defined above.

In another implementation of the present disclosure, an underfill material may contain the additive for inhibiting the ECM as defined above.

In still another implementation of the present disclosure, a metal electrical wire may contain the additive for inhibiting the ECM as defined above.

In another embodiment of the present disclosure, a method for inhibiting electrochemical migration (ECM) in an electrical wire may include preparing an additive for inhibiting the ECM in an electrical wire, wherein the additive comprises at least one selected from a group consisting of ascorbic acid (C₆H₈O₆), carbohydrazide ((N₂H₃)₂CO), hydroquinone (C₆H₄-1,4-(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose:oxygen-1-oxidoreductase), cobalt sulfite (CoSO₃), nitrogen monoxide (NO), and hamamelitannin (2′,5-di-O-galloylhamamelose; C₂₀H₂₀O₁₄); adding the additive into a packaging material or an underfill material or an epoxy molding compound (EMC); and molding the electrical wire using the packaging material or an underfill material or EMC. The materials listed above may be added alone or in a combination of at least two thereof.

In this connection, the additive inhibits creation of dendrite in the electrical wire. The additive inhibits a cathode reaction involving in the electrochemical migration in the electrical wire, wherein the cathode reaction is represented by a following reaction formula: O₂2H₂O+4e⁻→4OH⁻.

Therefore, in accordance with the present disclosure, the removal of the oxygen using the additive (oxygen scavenger) inhibits the creation of OH⁻, thereby inhibiting the reaction between the electrodes, that is, the anode and cathode, involving in OH⁻. Thus, the present additive may be considered to be more effective in suppressing the ECM creation in various metals present in a semiconductor device.

When comparing a solution containing the ECM-inhibiting additive as proposed in accordance with the present disclosure with the convention solution, it was confirmed that the solution containing the ECM-inhibiting additive may inhibit the creation of dendrite to prolong the ECM time. For this purpose, the present additive was added to a solution for an existing water drop test as a high-acceleration test to measure sensitivity of the ECM. Then, a time for which dendrite grows to extend between two metal electrical wires was measured. The time refers to the electrochemical migration time or ECM time.

The additive proposed in accordance with the present disclosure may be mixed with polymer materials such as epoxy molding compound (EMC) or underfill materials used for packaging a semiconductor, or the like. Alternatively, the additive proposed in accordance with the present disclosure may be added to metal electrical wires to improve the reliability of semiconductor devices.

Hereinafter, in order to describe the present disclosure more specifically, specific examples will be described.

### PRESENT EXAMPLE 1

### Preparation of ECM-Inhibiting Additive-Containing Solution

Sodium chloride (NaCl) was added into deionized water with an electrical conductivity of 15 MΩ or higher to prepare solutions with low and high concentrations of chloride ions. The chloride ion accelerates ionization reaction of an anode metal thereby to promote ECM phenomenon. Thus, in the present experiment, the chloride ion solution was set as an accelerating environment or solution.

Thus, the low concentration chloride ion solution simulates a mild environment while the high concentration chloride ion solution simulates a corrosive environment. The present additive was added to this accelerating solution to evaluate the effect of the present additive.

In the present experiment, each of ascorbic acid (C₆H₈O₆) (hereinafter, A.A), carbohydrazide ((N₂H₃)₂CO) (hereinafter, C.H), hydroquinone (C₆H₄-1,4-(OH)₂) (hereinafter, H.Q), and diethylhydroxylamine (DEHA: (C₂H₅)₂NOH) (hereinafter, D.H.A) as the ECM-inhibiting additive was added to the chloride ion solution as the accelerating solution.

The present experiments were carried out using each single-additive containing solution into which each additive was added in a concentration-dependent (100, 200, 300, 400, and 500 ppm) manner In addition, each various-additives containing solution was prepared using additives, each additive achieving, in each single-additive containing solution experiment, an ECM time larger than an ECM time obtained using a reference solution. Each various-additives containing solution was prepared in a concentration-dependent manner Each solution was sufficiently stirred and then was sufficiently aged for stabilization.

### PRESENT EXAMPLE 2

### Evaluation of ECM Inhibiting Performance of Single-Additive and Various-Additive Containing Solutions

The present experiment in each ECM-inhibiting additive containing solution was dropped to between copper electrical wires or to between silver electrical wire in an equal amount was performed to measure each ECM time. The experiment was conducted at least five times for each solution.

### Experimental Example 1: Drop Test Using Each Single ECM-Inhibiting Additive Containing Solution

In this experiment, each single ECM-inhibiting additive containing solution was dropped to between copper electrical wires or to between silver electrical wires as formed of a comb type according to IPC-TM-650. Then, voltage was applied to both copper electrical wires and to both silver electrical wires. Thus, a time and a process for and in which dendrite grows to connect both copper electrical wires with each other and to connect both silver electrical wires with each other. In this experiment, a voltage of 3V was applied thereto at an atmospheric condition (atmospheric temperature, and atmospheric humidity). The ECM time measurement was performed by recording video upon the voltage application.

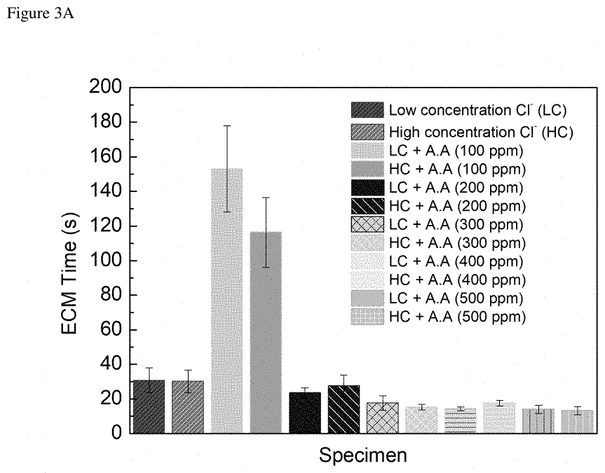

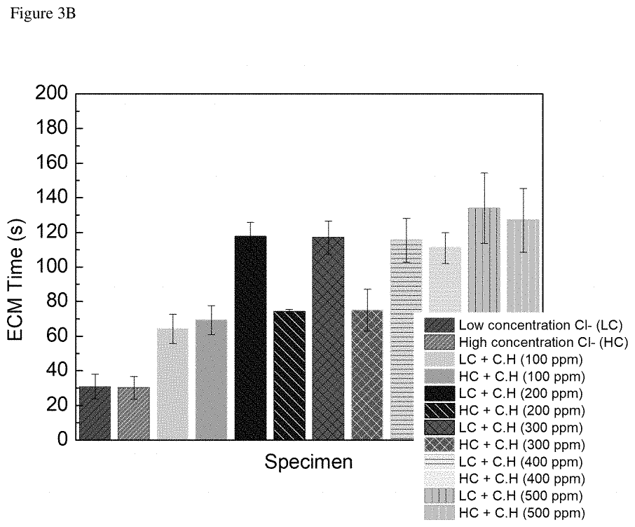

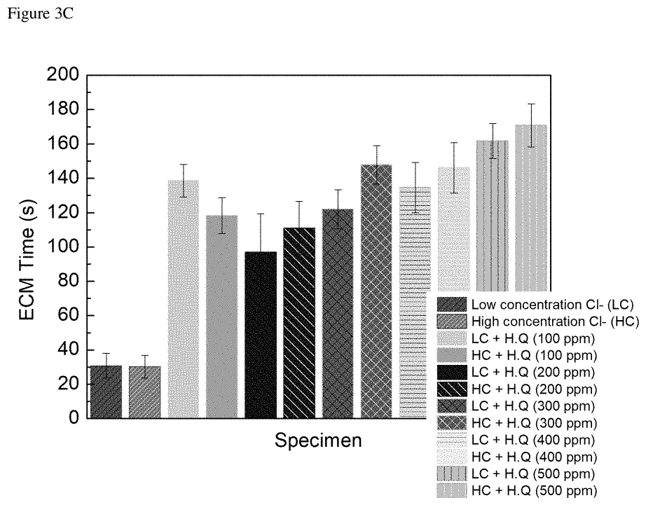

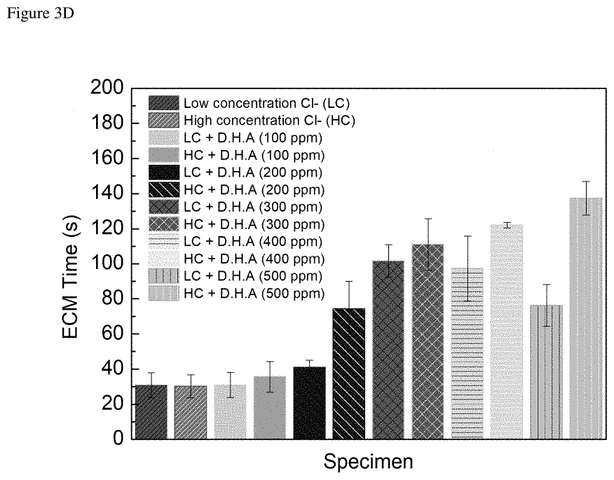

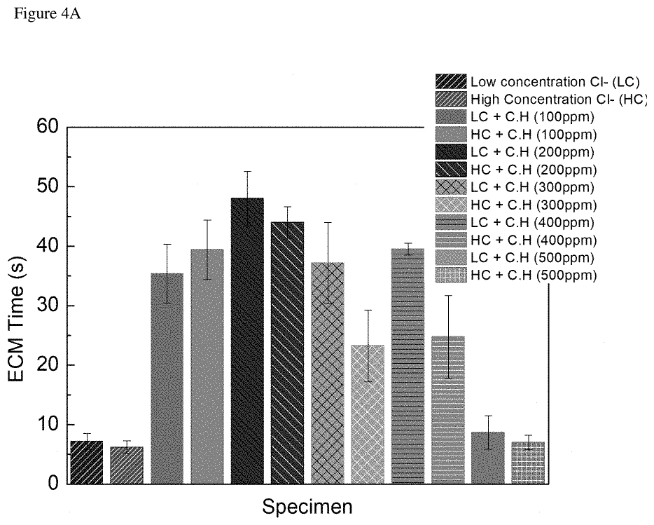

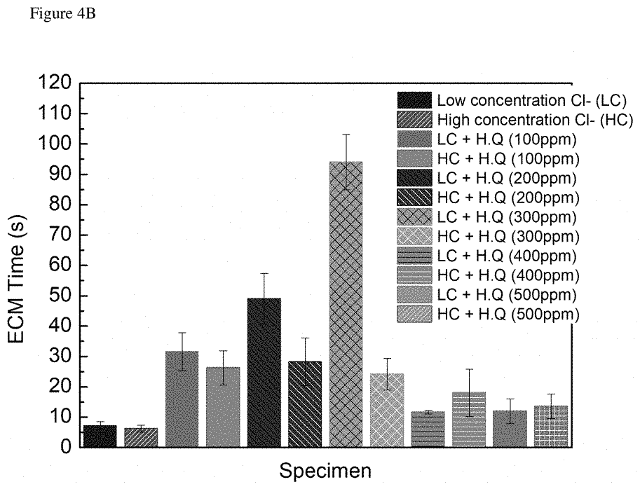

FIG. 3A to FIG. 3D show an average and a standard deviation of an ECM time based on concentrations of a reference solution and each single-additive containing solution according to the present disclosure for a copper electrical wire. FIG. 4A and FIG. 4B show an average and a standard deviation of an ECM time based on concentrations of a reference solution and each single-additive containing solution according to the present disclosure for a silver electrical wire.

### Experimental Example 2: Drop Test Using Various ECM-Inhibiting Additives Containing Solution

For this experiment, each various-additives containing solution was prepared using additives, each additive achieving, in each single-additive containing solution experiment, that is, in the Experimental Example 1, the ECM time larger than an ECM time obtained using the reference solution. Each various-additives containing solution was prepared in a concentration-dependent manner.

In this experiment, each various ECM-inhibiting additives containing solution was dropped to between copper electrical wires or to between silver electrical wires as formed of a comb type according to IPC-TM-650. Then, voltage was applied to both copper electrical wires and to both silver electrical wires. Thus, a time and a process for and in which dendrite grows to connect both copper electrical wires with each other and to connect both silver electrical wires with each other. In this experiment, a voltage of 3V was applied thereto at an atmospheric condition (atmospheric temperature, and atmospheric humidity). The ECM time measurement was performed by recording video upon the voltage application.

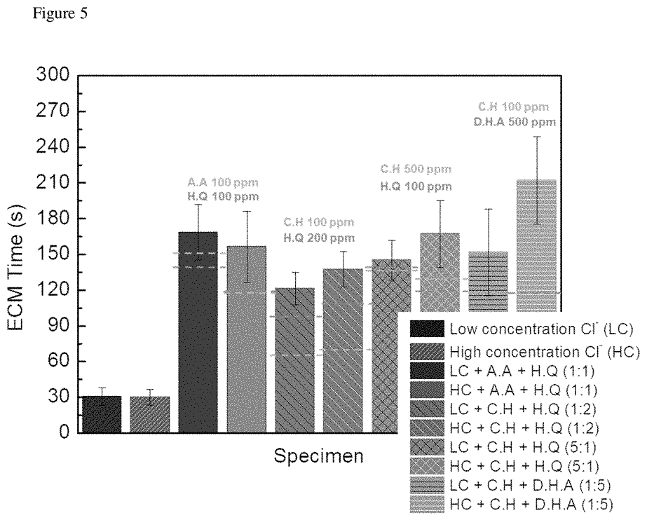

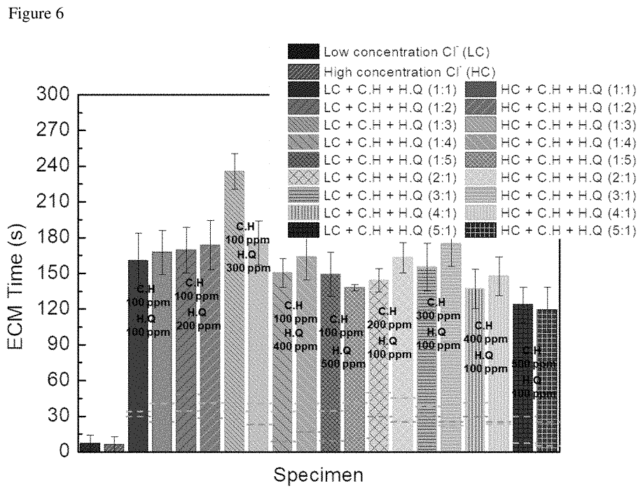

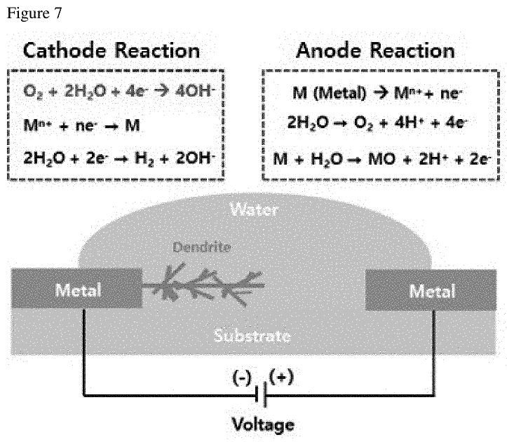

FIG. 5 shows an average and a standard deviation of an ECM time based on concentrations of each various-additives containing solution according to the present disclosure for a copper electrical wire. FIG. 6 shows an average and a standard deviation of an ECM time based on concentrations of each various-additives containing solution according to the present disclosure for a silver electrical wire. In FIG. 5 and FIG. 6, a dotted line denotes an ECM time measured for a corresponding single-additive containing solution.

### Results of Experimental Example 1

Referring to FIG. 3A to FIG. 3D, the solutions containing various ECM-inhibiting additives respectively show different ECM performance properties related to the copper electrical wires.

(A) Regarding the A.A, when 100 ppm thereof was added to the low and high concentration chloride ion solutions, the resulting ECM time was larger compared to that achieved by the reference solution. However, as the concentration of A.A in the low and high concentration chloride ion solutions increased, the measured ECM time decreased rapidly. Thus, the resulting ECM time may be similar to that achieved by the reference solution.

(B) Regarding the C.H, as the concentration of C.H in the low and high concentration chloride ion solutions increased, the resulting ECM time was increased and was larger than that achieved by the reference solution.

(C) Regarding the H.Q, as the concentration of H.Q in the low concentration chloride ion solution increased, the resulting ECM time was decreased and then increased. As the concentration of H.Q in the high concentration chloride ion solution increased, the resulting ECM time was increased. The resulting ECM time for the low and high concentration chloride ion solutions was larger than that achieved by the reference solution.

(D) Regarding the D.H.A, as the concentration of D.H.A in the low concentration chloride ion solution increased, the resulting ECM time increased and then decreased. As the concentration of D.H.A in the high concentration chloride ion solution increased, the resulting ECM time increased. When 100 ppm of D.H.A was added thereto, the resulting ECM time was similar to that achieved by the reference solution. The resulting ECM time except for the addition of the 100 ppm of D.H.A was larger than that achieved by the reference solution.

Thus, when each single ECM-inhibiting additive was added to the low and high concentration chloride ion solutions, the resulting ECM time related to the copper electrical wire was the largest at 100 ppm A.A, 500 ppm C.H, 500 ppm H.Q, 300 ppm D.H.A or 500 ppm D.H.A. In addition, the C.H, H.Q and D.H.A may be used as additives to inhibit the ECM in all concentration ranges depending on conditions.

Referring to FIG. 4A and FIG. 4B, the solutions containing various ECM-inhibiting additives respectively show different ECM performance properties related to the sliver electrical wires.

(A) Regarding the C.H, as the C.H concentration in the low and high concentration chloride ion solutions increased, the resulting ECM time increased and then decreased. The longest ECM time occurred when the C.H 200 ppm was added thereto. When 500 ppm of C.H was added thereto, the resulting ECM time was similar to that as measured when using the reference solution. The ECM time measured except for the 500 ppm of C.H was larger than that as measured when using the reference solution.

(B) Regarding the H.Q, as the H.Q concentration in the low and high concentration chloride ion solutions increased, the resulting ECM time increased and then decreased. When 440 or 500 ppm of H.Q was added thereto, the resulting ECM time was similar to that as measured when using the reference solution. The ECM time measured except for the 400 or 500 ppm of H.Q was larger than that as measured when using the reference solution. In particular, the addition of 300 ppm H.Q to the low concentration chloride ion solution increased the ECM time rapidly.

Therefore, when each single ECM-inhibiting additive was added to the low and high concentration chloride ion solutions, the resulting ECM time related to the sliver electrical wire was the largest at 200 ppm C.H and 300 ppm H.Q. In addition, C.H and H.Q may be used as additives to inhibit the ECM in all concentration ranges depending on conditions.

Among various reliability evaluation tests, the water drop test may be a useful experimental method to grow the dendrite under a severe condition and observe the dendrite in a short time. The water drop test achieves 1000 times (3 orders) of a dendrite growth rate achieved by a commonly used constant temperature and humidity test. Thus, the ECM time as measured in this experiment demonstrates that the present additive may be effective to suppress the ECM in the metal electrical wire used in the actual industrial field.

### Results of Experimental Example 2

For this experiment, each various-additives containing solution was prepared using additives, each additive achieving, in each single-additive containing solution experiment, that is, in the Experimental Example 1, the ECM time larger than an ECM time obtained using the reference solution. Each various-additives containing solution was prepared in a concentration-dependent manner All the tested solutions exhibited resulting ECM times larger than or equal to that as achieved by the reference solution for the copper and silver electrical wires.

FIG. 5 shows an average and a standard deviation of an ECM time based on concentrations of each various-additives containing solution according to the present disclosure for a copper electrical wire. FIG. 6 shows an average and a standard deviation of an ECM time based on concentrations of each various-additives containing solution according to the present disclosure for a silver electrical wire. In FIG. 5 and FIG. 6, a dotted line denotes an ECM time measured for a corresponding single-additive containing solution.

In a following ratio between concentrations of the additives, 1 means 100 ppm.

Referring to FIG. 5 related to the copper wire, when the ratios between concentrations of the additives are configured such that A.A:H.Q=1:1, C.H:H.Q=1:2, C.H:H.Q=5:1, and C.H:D.H.A=1:5, each various-additives containing solution exhibits better ECM inhibiting effect than each corresponding single-additive containing solution.

Referring to FIG. 6 related to the silver wire, when the ratios between concentrations of the additives are configured such that C.H:H.Q=1:1, 1:2, 1:3, 1:4, 1:5, 2:1, 3:1, 4:1, and 5:1, each various-additives containing solution exhibits better ECM inhibiting effect than each corresponding single-additive containing solution.

The oxygen scavenger (absorber) as the ECM-inhibiting additive in accordance with the present disclosure may be responsible for removing oxygen from the solution by reacting with oxygen present in the solution. The oxygen elimination reaction slows the O₂+2H₂O+4e⁻→4OH⁻ reaction in the cathode reaction leading to the ECM, thereby reducing the production of OH⁻. Thus, this may inhibit the formation of Cu(OH)₂ and Ag(OH) and the formation of CuO and Ag₂O to control the reduction rate of the cathode to the metal and thus the growth rate of dendrite.

A.A removes oxygen via a following reaction formula:

A.A+½O₂→D.H.A.A.+H₂O (D.H.A.A: dehydroascorbic acid)

C.H removes oxygen via a following reaction formula:

C.H+2O₂→2N₂+3H₂O+CO₂

H.Q removes oxygen via a following reaction formula:

H.Q.+½O₂→B.Q+H₂O (B.Q: Benzoquinone)

D.H.A removes oxygen via a following reaction formula:

D.H.A.+9O₂→8CH₃COOH+2N₂+6H₂O

When comparing a solution containing the ECM-inhibiting additive as proposed in accordance with the present disclosure with the convention solution, it was confirmed that the solution containing the ECM-inhibiting additive may inhibit the creation of dendrite to prolong the ECM time. For this purpose, the present additive was added to a solution for an existing water drop test as a high-acceleration test to measure sensitivity of the ECM. Then, a time for which dendrite grows to extend between two metal electrical wires was measured. The time refers to the electrochemical migration time or ECM time.

The additive proposed in accordance with the present disclosure may be mixed with polymer materials such as epoxy molding compound (EMC) or underfill materials used for packaging a semiconductor, or the like. Alternatively, the additive proposed in accordance with the present disclosure may be added to metal electrical wires to improve the reliability of semiconductor devices.

The ECM involves the oxygen reaction. Thus, the present additive may be applied not only to the copper and silver recited in the present disclosure but also to any metal subjected to the ECM.

The description of the presented embodiments is provided to enable any person skilled in the art to implement the present disclosure. Various modifications to these embodiments will be apparent to those of ordinary skill in the art according to the present disclosure. The general principle defined herein may be applied to other embodiments without departing from the scope of the present disclosure. Thus, the present disclosure should not be limited to the embodiments presented herein but should be interpreted in the broadest scope consistent with the principles and novel features set forth herein.

What is claimed is:

1. An additive for inhibiting electrochemical migration (ECM) in an electrical wire, the additive comprising at least one selected from a group consisting of ascorbic acid (C₆H₈O₆), carbohydrazide ((N₂H₃)₂CO), hydroquinone (C₆H₄-1,4-(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose:oxygen-1-oxidoreductase), cobalt sulfite (CoSO₃), nitrogen monoxide (NO), and hamamelitannin (2′,5-di-O-galloylhamamelose; C₂₀H₂₀O₁₄).

2. The additive for inhibiting the ECM of claim 1, wherein the additive inhibits creation of dendrite in the electrical wire.

3. The additive for inhibiting the ECM of claim 1, wherein the additive inhibits a cathode reaction involving in the electrochemical migration in the electrical wire, wherein the cathode reaction is represented by a following reaction formula:
O₂+2H₂O+4e⁻→4OH⁻.

4. An epoxy molding compound (EMC) containing the additive for inhibiting the ECM of claim 1.

5. An underfill material containing the additive for inhibiting the ECM of claim 1.

6. A metal electrical wire containing the additive for inhibiting the ECM of claim 1.

7. A method for inhibiting electrochemical migration (ECM) in an electrical wire, the method comprising:
preparing an additive for inhibiting the ECM in an electrical wire;
adding the additive into a packaging material, an underfill material or an epoxy molding compound (EMC); and
molding the electrical wire using the packaging material or underfill material or EMC,
wherein the additive comprises at least one selected from a group consisting of ascorbic acid (C₆H₈O₆), carbohydrazide ((N₂H₃)₂CO), hydroquinone (C₆H₄-1,4-(OH)₂), sodium sulfite (Na₂SO₃), potassium sulfite (K₂SO₃), sodium bisulfite (NaHSO₃), potassium bisulfite (KHSO₃), sodium metabisulfite (Na₂S₂O₅), ammonium bisulfate ((NH₄)HSO₄), hydrazine (N₂H₄), erythorbate (RC₆H₆O₆), diethylhydroxylamine (DEHA: (C₂H₅)₂NOH), methylethylketoxime (MEKO: C₄H₉NO), isopropylhydroxylamine (C₃H₉NO), alkylhydroxylamine (H₃NO), 1-aminopyrrolidine (C₄H₁₀N₂), 1-amino-4-methylpiperazine (1A4MP; C₅H₁₃N₃), saccharide, sulfur trioxide (SO₃), sulfur dioxide (SO₂), iron powder, boron (B), sugar alcohols, glycol, unsaturated fatty acids, hydrocarbons, palladium catalysts, enzymes, yeast, organometallic ligands, photosensitive dyes, polydiene block copolymers, polymer-bound olefins, aromatic nylon, glucose-1-oxidase (-D-glucose: oxygen-1-oxidoreductase), cobalt sulfite (CoSO₃), nitrogen monoxide (NO), and hamamelitannin (2′,5-di-O-galloylhamamelose; C₂₀H₂₀O₁₄).

8. The method of claim 7, wherein the additive inhibits creation of dendrite in the electrical wire.

9. The method of claim 7, wherein the additive inhibits a cathode reaction involving in the electrochemical migration in the electrical wire, wherein the cathode reaction is represented by a following reaction formula:
O₂+2H₂O+4e⁻→4OH⁻.
